(19) United States
(12) Patent Application Publication
(10) Pub. No.: US 2010/0090589 A1
(43) Pub. Date: Apr. 15, 2010

(54) ORGANIC EL DISPLAY

(75) Inventors: Yuusuke ITAGAKI, Ishikawa-ken (JP); Hirofumi KUBOTA, Ishikawa-ken (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Toshiba Mobile Display Co., Ltd., Tokyo (JP)

(21) Appl. No.: 12/501,720

(22) Filed: Jul. 13, 2009

(30) Foreign Application Priority Data
Oct. 9, 2008 (JP) 2008-263113

(51) Int. Cl. H01J 1/62

(52) U.S. Cl. 313/504

(57) ABSTRACT

An organic EL display comprises an electrode layer including reflecting film; a counter electrode provided in front of said electrode layer; and an organic material layer including a light emitting layer provided between said electrode layer and said counter electrode; wherein said counter electrode includes a first conductive electrode and a second conductive electrode which is provided in front of said first conductive electrode, said first conductive electrode is made of silver (Ag) or an alloy of silver and magnesium (MgAg) whose principal element is silver (Ag), and said second conductive electrode is made of an alloy of silver and magnesium (MgAg) whose principal element is magnesium (Mg).

### CROSS-REFERENCE TO RELATED APPLICATIONS

This application is based upon and claims the benefit of priority from prior Japanese Patent Application No. 2008-263113, filed Oct. 9, 2008, the entire contents of which are incorporated herein by reference.

### BACKGROUND OF THE INVENTION

1. Field of the Invention

The present invention relates to a organic EL display.

2. Description of the Related Art

In recent years, attention has been paid to an organic electroluminescence (EL) display as a display device. Since the organic EL display includes self-luminous display elements, the organic EL display has such features that the viewing angle is wide, no backlight is needed and thus reduction in thickness can be achieved, power consumption can be decreased, and high responsivity is obtained. Furthermore, the organic EL display is mercury-free because it needs no backlight such as cold cathode fluorescent lamp (CCFL).

For these reason, the organic EL display attracts attention as a display for a notebook PC, a monitor and TV.

The organic EL display has an array substrate. The array substrate comprises a glass substrate and a plurality of organic EL elements provided on the glass substrate in a matrix shape. Each of the organic EL elements is comprised in one sub-pixel. Each of the organic EL elements includes an anode electrode, a cathode electrode facing the anode electrode, and a light emitting layer therebetween.

The light emitting layer includes an organic material having a light emitting function and is able to emit one of a red light, a green light and a blue light. This organic EL display has a micro cavity structure which can resonate the emitting light from the light emitting layer (see, e.g. Jpn. Pat. Appln. KOKAI Publication No. 2007-157732).

Furthermore, a technique of thickening the cathode electrode for enhancing the effect of micro cavity is studied. However, in that case, there is a problem that the reflectivity of the outside light at the surface of the cathode electrode is increasing. Thus, the organic EL display is desired to have a strong effect of micro cavity and a weak effect of the reflectivity of the outside light.

### BRIEF SUMMARY OF THE INVENTION

The present invention has been made in consideration of the above-described problems, and the object of the invention is to provide an organic EL display which has a strong effect of micro cavity and a weak effect of the reflectivity of the outside light.

According to a first aspect of the present invention, there is provided an organic EL display comprising: an electrode layer including reflecting film; a counter electrode provided in front of said electrode layer; and an organic material layer including a light emitting layer provided between said electrode layer and said counter electrode; wherein said counter electrode includes a first conductive electrode and a second conductive electrode which is provided in front of said first conductive electrode, said first conductive electrode is made of silver (Ag) or an alloy of silver and magnesium (MgAg) whose principal element is silver (Ag), and said second conductive electrode is made of an alloy of silver and magnesium (MgAg) whose principal element is magnesium (Mg).

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

The accompanying drawings, which are incorporated in and constitute a part of the specification, illustrate presently preferred embodiments of the invention, and together with the general description given above and the detailed description of the preferred embodiments given below, serve to explain the principles of the invention.

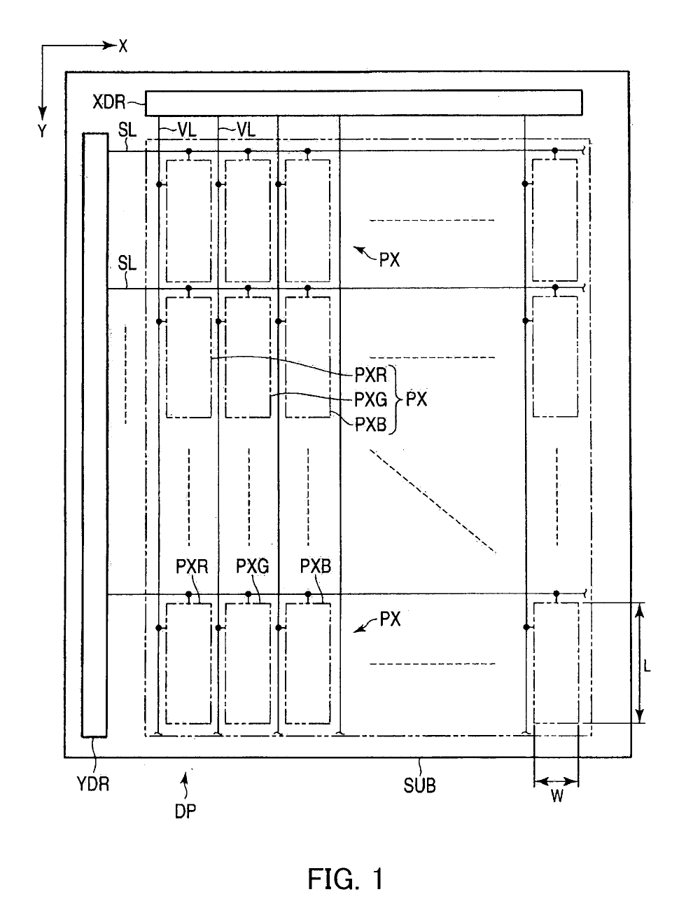

FIG. 1 schematically shows the structure of an organic EL display according to an embodiment of the present invention.

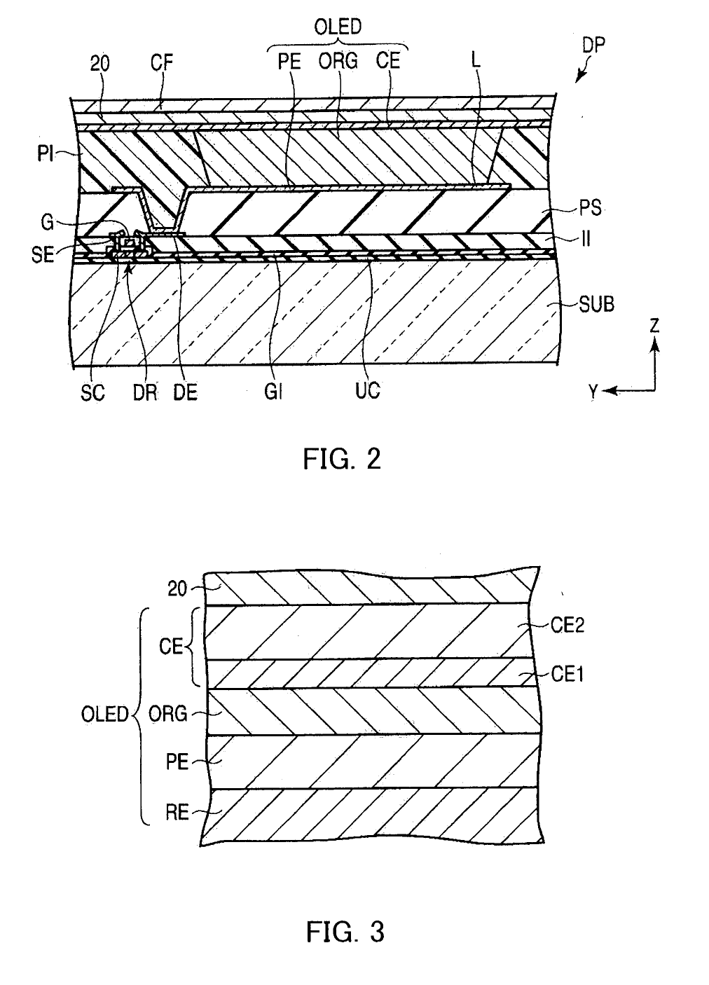

FIG. 2 is an enlarged cross-sectional view that schematically shows an organic EL display shown in FIG. 1.

FIG. 3 is an enlarged cross-sectional view that schematically shows an organic EL element shown in FIG. 2.

### DETAILED DESCRIPTION OF THE INVENTION

An organic EL display according to an embodiment of the present invention will now be described with reference to the accompanying drawings. In the FIG. 2, the front surface of the organic EL display is upper side and the rear surface is down side. The emitting light generated by a light emitting layer goes through the front surface. The organic EL display in this embodiment adopts an active matrix manner and is a top emission type.

As is shown in FIG. 1, an organic EL display includes an organic EL panel DP, a video line driver XDR and a scan line driver YDR. The organic EL panel DP includes a plurality of pixels PX in a matrix manner. Each of the pixels comprises three sub-pixels which are a red sub-pixel PXR, a green sub-pixel PXG and a blue sub-pixel PXB. The red sub-pixel PXR emits a red light, the green sub-pixel PXG emits a green light and the blue sub-pixel PXB emits a blue light.

As are shown in FIGS. 1 and 2, the organic EL panel DP includes an insulated substrate SUB such as a glass substrate. An undercoat layer UC is provided on the substrate SUB. The undercoat layer UC comprises, for example, a silicon nitride (SiNx) layer and a silicon oxide (SiOx) layer thereon.

A plurality of channel layers SC are arranged on the undercoat layer UC. The channel layer SC is made of polysilicon. The channel layer SC is covered by a gate insulating film GI. The gate insulating film GI can be made by, for example, tetraethyl orthosilicate (TEOS).

A plurality of scan lines SL and gate electrodes G are provided on the gate insulating film GI. The scan lines SL are extended in row direction (X direction) in the matrix of the pixels PX and arranged in column direction (Y direction). The scan line SL is made of, for example, molybdenum-tungsten (MoW). The gate electrode G has an intersection with the channel layer SC, and the intersection forms a driving transistor DRT. In this embodiment, the driving transistor DRT is a thin film transistor of a top-gate type.

The gate insulating film GI, the scan line SL and the gate electrode G are covered by a interlayer insulating film II. The interlayer insulating film II is made of, for example, a silicon oxide (SiOx) which is formed by plasma chemical vapor deposition (CVD) method.

A plurality of video lines VL are provided on the interlayer insulating film II. The video lines VL are extended in column direction (Y direction) in the matrix of the pixels PX and arranged in row direction (X direction). The scan line SL and the video line VL are connected to the sub-pixels.

A plurality of source electrodes SE and drain electrodes DE are also provided on the interlayer insulating film II. The source electrode SE and the drain electrode DE are connected to a source region and a drain region in the channel layer SC respectively through contact holes formed in the interlayer insulating film II and the gate insulating film GI.

The video line VL, the source electrode SE and the drain electrode DE are covered by a passivation film PS as shown in FIG. 2. The passivation film PS is made of, for example, silicon nitride (SiNx). A plurality of electrode layer L are arranged on the passivation film PS. The electrode layer L is connected to the drain electrode DE of the driving transistor DRT through a contact hole formed in the passivation film PS.

In this example, the electrode layer L has a three-layer structure which comprises a layer made of indium tin oxide (ITO), a layer made of silver (Ag) and a layer made of ITO.

The layer made of silver in the electrode layer L is a reflecting film. The upper layer made of ITO in the electrode layer L is a pixel electrode PE. In this embodiment, the pixel electrode PE functions as an anode electrode. A partition insulating layer PI is provided on the passivation film PS. The partition insulating layer PI has through holes or slits corresponding to the regions of the pixel electrodes PE. In this embodiment, the partition insulating layer PI has through holes. The partition insulating layer PI is, for example, an organic insulating layer. The partition insulating layer PI is formed by, for example, using a photolithography technique.

As are shown in FIG. 2 and FIG. 3, an organic material layer ORG on the pixel electrode PE. The organic material layer ORG includes a light emitting layer and functions as an active layer. The light emitting layer is a thin film made of an organic compound having luminescence characteristics. The organic material layer ORG can include not only the light emitting layer but also a hole injecting layer, a hole transporting layer, an electron transporting layer and/or an electron injecting layer.

As are shown in FIGS. 1, 2 and 3, the partition insulating layer PI and the organic material layer ORG are covered by a counter electrode CE. In this embodiment, the counter electrode CE is common to all pixels PX, and the counter electrode CE functions as a cathode electrode and has a transparent characteristic.

An organic EL element OLED includes the reflecting film RE, the pixel electrode PE, the organic material layer ORG and the counter electrode CE. Each one of the red sub-pixel, the green sub-pixel and the blue sub-pixel including the driving transistor DRT and the organic EL element OLED.

A protective film 20 is provided on the organic EL elements OLED. In more detail, the protective film 20 is provided on the counter electrode CE. The protective film 20 prevents the moisture or oxygen from entering into the organic EL element OLED and reduces deterioration of the characteristics of the organic EL element OLED.

A color filter CF is provided on the protective film 20. The color filter CF includes a red-colored layer, a green-colored layer and a blue-colored layer. The red-colored layer, the green-colored layer and the blue-colored layer overlap the red sub-pixel PXR, the green sub-pixel PXG and the blue sub-pixel PXB respectively.

The video line driver XDR and the scan line driver YDR are mounted on the substrate SUB in a chip on glass (COG) manner. The video lines are connected to the video line driver VDR, and the scan lines are connected to the scan line driver YDR.

Next, the counter electrode CE will be described in more detail. As are shown in FIGS. 2 and 3, the counter electrode CE is provided in front of the pixel electrode PE. The counter electrode CE is a two-layered structure. The counter electrode CE has a first conductive electrode CE1 and a second conductive electrode CE2. The first conductive electrode CE1 is provided on the organic material layer ORG and is made of silver (Ag) or an alloy of silver and magnesium (MgAg) whose principal element is silver (Ag). The second conductive electrode CE2 is provided in front of the first conductive electrode CE1 and is made of an alloy of silver and magnesium (MgAg) whose principal element is magnesium (Mg).

In this embodiment, the ratio of weight of Mg to Ag in the first conductive electrode CE1 is 5 to 95. And the ratio of weight of Mg to Ag in the second conductive electrode CE2 is 90 to 10.

The inventors of this invention compared the organic EL display of this embodiment with a comparative example regarding the reflectivity of the outside light.

The comparative sample was same structure as one of this embodiment without the structure of counter electrode. The counter electrode of the comparative sample comprised only one layer which was same composition as the first conductive electrode CE1 of this embodiment, and the total thickness of the counter electrode of the comparative example was same as total thickness of the counter electrode CE of this embodiment.

As the result of the experiment, in the emission peak wavelengths which indicates a peak wavelength of red, green and blue, there was no remarkable difference of the reflectivity of the outside light between the organic EL display of this embodiment and the comparative sample. However, in the range out of the emission peak wavelength, the reflectivity of the outside light of the organic EL display of this embodiment was higher than that of the comparative sample. Regarding the micro-cavity effect, there was no remarkable difference between them.

In order to enjoy the micro-cavity effect, the counter electrode CE is desired to have silver mainly which has high reflectivity characteristics and have a certain amount of thickness. However, if the counter electrode CE is made of only silver-rich material and is increasing the thickness, the reflectivity of the outside light is increasing. As the result, the contrast of the display is decreased. The inventors found that the silver component near the organic material layer ORG mainly effects on the micro-cavity effect. Therefore, the organic EL display can get the enough micro-cavity effect with the low reflectivity of the outside light at the counter electrode CE according to this embodiment which comprises the silver-rich first conductive electrode CE1 on the organic material layer ORG and the magnesium-rich second conductive electrode CE2 on the first conductive electrode CE1.

In this embodiment, the color filter CF is used in the organic EL display. By using the color filter CF, the reflectivity of the outside light can be decreased and color purity of the emitting light can be advanced.

However, even if the organic EL display without the color filter CF, this invention is effective.

The present invention is not limited directly to the above-described embodiments. In practice, the structural elements can be modified without departing from the spirit of the invention. Various inventions can be made by properly combining the structural elements disclosed in the embodiments. For example, some structural elements may be omitted from all the structural elements disclosed in the embodiments. Furthermore, structural elements in different embodiments may properly be combined.

What is claimed is:

1. An organic EL display comprising:
an electrode layer including reflecting film;
a counter electrode provided in front of said electrode layer; and
an organic material layer including a light emitting layer provided between said electrode layer and said counter electrode;
wherein said counter electrode includes a first conductive electrode and a second conductive electrode which is provided in front of said first conductive electrode, said first conductive electrode is made of silver (Ag) or an alloy of silver and magnesium (MgAg) whose principal element is silver (Ag), and said second conductive electrode is made of an alloy of silver and magnesium (MgAg) whose principal element is magnesium (Mg).

2. The organic EL display according to claim 1, further comprising a color filter provided in front of said counter electrode.

3. The organic EL display according to claim 1, wherein the ratio of weight of Mg to Ag in said first conductive electrode is substantially 5 to 95.

4. The organic EL display according to claim 1, wherein the ratio of weight of Mg to Ag in said second conductive electrode is substantially 90 to 10.

5. The organic EL display according to claim 1, further comprising a substrate provided behind said electrode layer.
